(19) United States
(12) Patent Application Publication
(10) Pub. No.: US 2025/0130254 A1
(43) Pub. Date: Apr. 24, 2025

(54) POGO PIN WITH MULTI-STAGE BRUSH SETS

(71) Applicant: IWIN SOLUTION CORPORATION, Cheongju-si (KR)

(72) Inventor: Sangyang PAK, Cheongju-si (KR)

(73) Assignee: IWIN SOLUTION CORPORATION, Cheongju-si (KR)

(21) Appl. No.: 18/907,270

(22) Filed: Oct. 4, 2024

(30) Foreign Application Priority Data
Oct. 18, 2023 (KR) 10-2023-0139520

(51) Int. Cl. G01R 1/067; H01R 13/24

(52) U.S. Cl. CPC G01R 1/06722; H01R 13/2421

(57) ABSTRACT

Proposed is a pogo pin including a plunger module (1) guided by a barrel (3) and whose length exposed to an outside of the barrel (3) is variable, wherein the plunger module (1) includes a first brush set (11) in which a plurality of brushes with a first side thereof fixed and a second side thereof elastically contacting an inner surface of the barrel (3) is arranged in an annular shape, and a second brush set (21) in which a plurality of brushes with a first side thereof fixed and a second side thereof elastically contacting the inner surface of the barrel (3) is arranged in an annular shape.

### CROSS REFERENCE TO RELATED APPLICATION

The present application claims priority to Korean Patent Application No. 10-2023-0139520, filed Oct. 18, 2023, the entire contents of which is incorporated herein for all purposes by this reference.

### BACKGROUND

### Technical Field

The present disclosure relates to a pogo pin having a multi-stage brush set with two or more brush sets.

### Description of the Related Art

The patent document is an earlier application by the present applicant and discloses a pogo pin for ultra-high current provided with an external barrel that has a built-in spring that elastically supports a probe and guides the sliding of the probe, wherein the pogo pin is characterized by being composed of a sleeve provided with: a cylindrical coupling portion that surrounds a part of the probe and is fixed by combining with the part; and a plurality of brushes extending from the cylindrical coupling portion and sliding while elastically contacting the inner peripheral surface of the external barrel. The pogo pin according to the patent document has the advantage of improving the electrical characteristics of the pogo pin and transmitting a large current with a small contact resistance by providing the plurality of brushes that make elastic contact with the external barrel.

As the number of pins in semiconductor devices increases and the power consumption of semiconductor devices increases, high-performance pogo pins with smaller contact resistance and higher current carrying capabilities are required. For example, when attempting to transmit a higher current without reducing the resistance between a plunger equipped with a brush and an external barrel, burning may occur at the contact point between the brush and the external barrel.

In pogo pins with brushes, such as the pogo pin according to the invention of the previous application, the pressure of a brush applied to an inner wall of an external barrel is very small compared to the pressure applied to both ends of a pogo pin in the longitudinal direction, and the pressure of the brush applied to the inner wall of the external barrel being small becomes a factor in increasing the contact resistance between one brush and the external barrel. However, it is not easy to increase the pressure between the external barrel and the brush.

### DOCUMENT OF RELATED ART

(Patent Document 1) Korean Patent Application Publication No. 10-2022-0143545 (Published Oct. 25, 2022)

### SUMMARY

Accordingly, the present disclosure has been made keeping in mind the above problems occurring in the related art, and the present disclosure is intended to provide a pogo pin that further reduces the contact resistance between a plunger provided with a brush and an external barrel.

In addition, an objective of the present disclosure is to provide a high-performance pogo pin that further enhances current carrying capabilities.

In order to achieve the above objective, according to an aspect of the present disclosure, there is provided a pogo pin including: a plunger module 1 guided by a barrel 3 and whose length exposed to an outside of the barrel 3 is variable, wherein the plunger module 1 may include: a first brush set 11 in which a plurality of brushes with a first side thereof fixed and a second side thereof elastically contacting an inner surface of the barrel 3 is arranged in an annular shape; and a second brush set 21 in which a plurality of brushes with a first side thereof fixed and a second side thereof elastically contacting the inner surface of the barrel 3 is arranged in an annular shape.

According to an aspect of the present disclosure, there is provided a pogo pin including: a cylindrical barrel 3; one or two plunger modules 1 guided by the barrel 3 and whose length exposed to an outside of the barrel 3 is variable; and a coil spring 4 elastically supporting the one or two plunger modules 1, wherein at least one plunger module 1 of the one or two plunger modules 1 may include: a first plunger part 10 including: a first cylindrical portion 12; and a first brush set 11 in which a plurality of brushes with a first side thereof connected to the first cylindrical portion 12 and a second side thereof elastically contacting an inner surface of the barrel 3 is arranged in an annular shape; and a second plunger part 20 including: a second cylindrical portion 22 interpolated into the first cylindrical portion 12 and fixed to the first cylindrical portion 12; and a second brush set 21 in which a plurality of brushes with a first side thereof connected to the second cylindrical portion 22 and a second side thereof elastically contacting the inner surface of the barrel 3 is arranged in an annular shape.

In the pogo pin, a maximum outer diameter encompassing the brushes in the first brush set 11 before assembling the plunger module 1 to the barrel 3 may be larger than an inner diameter of the barrel 3 with which the first brush set 11 contacts, and a maximum outer diameter encompassing the brushes in the second brush set 21 before assembling the plunger module 1 to the barrel 3 may be larger than the inner diameter of the barrel 3 with which the second brush set 21 contacts.

In the pogo pin, wherein in the first brush set 11, each brush may be a straight strap, and before assembling a first plunger module 1 of the one or two plunger modules 1 to the barrel 3, the first brush set 11 may form a conical shape and may be connected to the first cylindrical portion 12 with a gap between the brushes, and in the second brush set 21, each brush may be a straight strap, and before assembling the first plunger module 1 of the one or two plunger modules 1 to the barrel 3, the second brush set 21 may form a conical shape and may be connected to the second cylindrical portion 22 with a gap between the brushes.

In the pogo pin, the first plunger part 10 may be made by a process including bending a single punched flat material, and the second plunger part 20 may be made by a process including bending a single punched flat material.

In the pogo pin, on an inner surface of the first cylindrical portion 12, an annular convex portion in which an inwardly convex protrusion is formed in an annular shape along a circumference of the first cylindrical portion 12 may be provided, whereas on an outer surface of the second cylindrical portion 22, an annular concave portion in which an inwardly concave groove is formed in an annular shape along a circumference of the second cylindrical portion 22 may be provided, and as the annular concave portion is seated on the annular convex portion, the second cylindrical portion 22 is fixed to the first cylindrical portion 12.

In the pogo pin, a second coupling cylindrical portion of a cylindrical shape may be provided on an outer side of the second cylindrical portion 22 in a longitudinal direction so as to fit into an inner surface of a first coupling cylindrical portion, which is located on a longitudinal inner side of the first cylindrical portion 12 and has a cylindrical shape, wherein before the second coupling cylindrical portion is coupled to the first coupling cylindrical portion, an outer diameter of the second coupling cylindrical portion may be larger than an inner diameter of the first coupling cylindrical portion, and a slit may be formed along a longitudinal direction in the second coupling cylindrical portion, wherein a width of the slit may be reduced or may disappear as the second coupling cylindrical portion is coupled to the first coupling cylindrical portion.

In the pogo pin, a length of the second coupling cylindrical portion may be equal to or longer than a length of the first coupling cylindrical portion, so that an upper end of the second coupling cylindrical portion may be caught by a step d8 created in the first cylindrical portion, and an outer diameter of the cylindrical portion provided successively to the first coupling cylindrical portion may be formed to be smaller than that of the first coupling cylindrical portion, thereby creating the step d8.

The pogo pin may further include a third plunger part 80 including: a third cylindrical portion 82 fitted into the second cylindrical portion 22 of the second plunger part 20; and a third brush set 81 in which a plurality of brushes with a first end thereof fixed to the third cylindrical portion 82 and a free end thereof elastically contacting the barrel 3 is arranged in an annular shape.

In the pogo pin, a maximum outer diameter encompassing the brushes in the first brush set 11 before assembling the at least one plunger module 1 of the one or two plunger modules 1 to the barrel 3 may be larger than an inner diameter of the barrel 3 with which the first brush set 11 contacts, and a maximum outer diameter encompassing the brushes in the second brush set 21 before assembling the at least one plunger module 1 of the one or two plunger modules 1 to the barrel 3 may be larger than the inner diameter of the barrel 3 with which the second brush set 21 contacts.

According to an aspect of the present disclosure, there is provided a pogo pin including: a first plunger 8 guided by a barrel 9 and whose length exposed to an outside of the barrel 9 is variable, wherein the first plunger 8 may include a first brush set 51 in which a plurality of brushes with a first end thereof fixed and a second end thereof elastically contacting an inner surface of the barrel 9 is arranged in an annular shape, wherein in the first brush set 51, each of the brushes may be strap shaped but may be shaped like a hook bent at least 135 degrees, before assembling the first plunger to the barrel, in an opposite direction in a middle part thereof.

The pogo pin may further include a second plunger 7 guided by the barrel 9, whose length exposed to an outside of the barrel 9 is variable, and configured opposite the first plunger 8, wherein the second plunger 7 may include a second brush set in which a plurality of brushes with a first end thereof fixed and a second end thereof elastically contacting the inner surface of the barrel 9 is arranged in an annular shape, wherein in the second brush set, each of the brushes may be a straight strap.

According to an aspect of the present disclosure, since a brush set is composed of two or more stages (multi-stage configuration), the contact area where a plunger module contacts a barrel is significantly increased, and the total contact resistance between the plunger module and the external barrel can be further reduced. As a result, the electrical resistance in a main electrical path is significantly reduced, and current carrying capabilities of a pogo pin can be significantly enhanced.

According to an aspect of the present disclosure, since two coupling cylindrical portions are in close contact with each other, the electrical resistance between the two coupling cylindrical portions is greatly reduced.

According to an aspect of the present disclosure, by using a brush set with a bent brush, the brush set can be more easily inserted into the opening of the barrel when inserting in the reverse direction, and it is easier to climb over an annular convex portion on the inner side of the barrel.

According to an aspect of the present disclosure, since an elastic distance of the brush is the overlap between an elastic distance created by a first strap portion m1 and an elastic distance created by a second strap portion m2, the elastic distance of the brush can be increased.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is an external view showing a pogo pin according to a first embodiment of the present disclosure;

FIG. 2 is an exploded perspective view showing the pogo pin according to the first embodiment of the present disclosure;

FIG. 3 is a vertical cross-sectional view showing the pogo pin according to the first embodiment of the present disclosure;

FIGS. 4A and 4B are perspective views showing a first plunger module and a second plunger module in the pogo pin according to the first embodiment of the present disclosure;

FIGS. 5A and 5B show a first modified example of the pogo pin according to the first embodiment of the present disclosure;

FIGS. 6A and 6B show a second modified example of the pogo pin according to the first embodiment of the present disclosure;

FIGS. 7A to 7C show a third modified example of the pogo pin according to the first embodiment of the present disclosure;

FIGS. 8A to 8C show a fourth modified example of the pogo pin according to the first embodiment of the present disclosure;

FIGS. 9A and 9B shows a pogo pin according to a second embodiment of the present disclosure, with FIG. 9A being a perspective view and FIG. 9B being a cross-sectional view taken along the line D-D;

FIG. 10 is a perspective view showing a first plunger in the pogo pin according to the second embodiment of the present disclosure; and

FIG. 11 is a cross-sectional view showing a brush in the pogo pin according to the second embodiment of the present disclosure.

### DETAILED DESCRIPTION

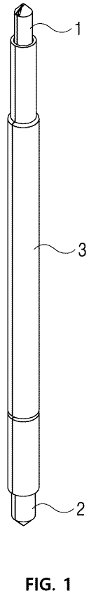

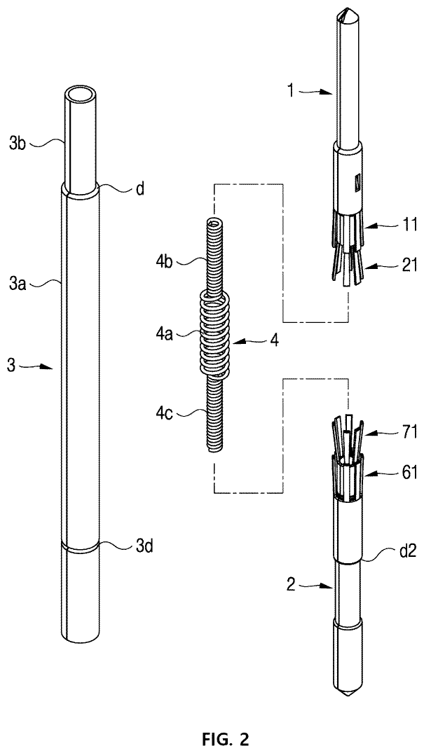

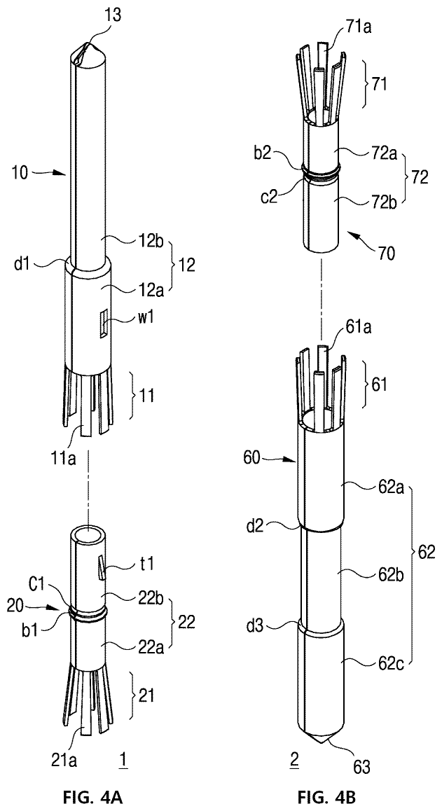

Hereinafter, a pogo pin according to a first embodiment of the present disclosure will be described in detail with reference to FIGS. 1 to 4.

The pogo pin according to the first embodiment of the present disclosure includes a first plunger module 1, a second plunger module 2, a barrel 3 and a coil spring 4.

The barrel 3 is approximately cylindrical in shape with a slight change in outer diameter, and consists of a first barrel cylindrical portion 3a and a second barrel cylindrical portion 3b having an outer diameter slightly smaller than that of the first barrel cylindrical portion 3a. At the longitudinal lower portion of the first barrel cylindrical portion 3a, an annular concave portion 3d formed in an annular shape along the circumference of the first barrel cylindrical portion 3a and forming a concave groove from the surface of the first barrel cylindrical portion 3a is provided. The annular concave portion 3d is for preventing the second plunger module 2 from being separated outward in the longitudinal direction due to a step d2 of a fourth plunger part 60 being caught in the annular concave portion 3d of the second plunger module 2.

The coil spring 4 elastically supports the first plunger module 1 and the second plunger module 2, with one end thereof elastically supports the first plunger module 1 and the other end thereof elastically supports the second plunger module 2. The coil spring 4 has a spring enlarged diameter portion 4a at the center thereof in the longitudinal direction, and a first spring reduced diameter portion 4b and a second spring reduced diameter portion 4c having an outer diameter smaller than the spring enlarged diameter portion 4a on opposite sides, respectively, of the longitudinal direction. The first spring reduced diameter portion 4b passes through the center of a second brush set 21 in the first plunger module and is seated on a second cylindrical portion 22 (more specifically, a 2-1 cylindrical portion 22a) of a second plunger part 20, and the second spring reduced diameter portion 4c is seated on a fifth cylindrical portion 72 (more specifically, a 5-1 cylindrical portion 72a) of a fifth plunger part 70 in the second plunger module 2.

The first plunger module 1 and the second plunger module 2 are guided by the barrel 3 and the length of each of the first plunger module 1 and the second plunger module 2 exposed to the outside of the barrel 3 is variable. In the drawing, the two plunger modules are coupled to opposite sides of the barrel 3 in the longitudinal direction, but depending on the application, configuration may be such that only one plunger module is coupled to the barrel 3 and on the other side of the barrel 3 is blocked.

In the first plunger module 1, a two-stage brush set including a first brush set 11 and the second brush set 21 is configured, whereas in the second plunger module 2, a two-stage brush set including a fourth brush set 61 and a fifth brush set 71 is configured. In the drawing, a two-stage brush set is configured on both the first plunger module 1 side and the second plunger module 2 side, but it is also possible to configure a one-stage brush set on one side and a two-stage brush set on the other side.

The first plunger module 1 includes a first plunger part 10 and a second plunger part 20 that are integrally coupled to each other, which means the first brush set 11 and the second brush set 21 are also integrally coupled to each other. Thus, when the pogo pin operates, all components constituting the first plunger module move together, and the first brush set 11 and the second brush set 21 arranged at regular intervals in the longitudinal direction also move together.

The first plunger part 10 includes: the first brush set 11; a first cylindrical portion 12 having a substantially cylindrical shape and including a 1-1 cylindrical portion 12a and a 1-2 cylindrical portion 12b; and a first probe portion 13, and constitutes a single part in which the three components (first brush set 11, first cylindrical portion 12, and first probe portion 13) are connected in order. The first probe portion 13 is a part for electrical contact with the outside, and the first plunger part 10 is formed by a process including bending, coining, blanking, and plating of a single punched flat material.

The first cylindrical portion 12 includes the 1-1 cylindrical portion 12a that serves as a base on which the brushes of the first brush set may be fixed, and the 1-2 cylindrical portion 12b connected to the 1-1 cylindrical portion 12a with a step d1 and having an outer diameter smaller than that of the 1-1 cylindrical portion 12a. Due to the step d1, the first plunger 1 is caught on the step d of the barrel 3 and is prevented from escaping to the outside. A first window w1 punched out in the shape of a small square window is formed at the longitudinal center of the 1-1 cylindrical portion, and by placing the free end of a first locking piece t1 provided on the second cylindrical portion 22 on the first window w1, the second plunger part is prevented from being separated from the first plunger part.

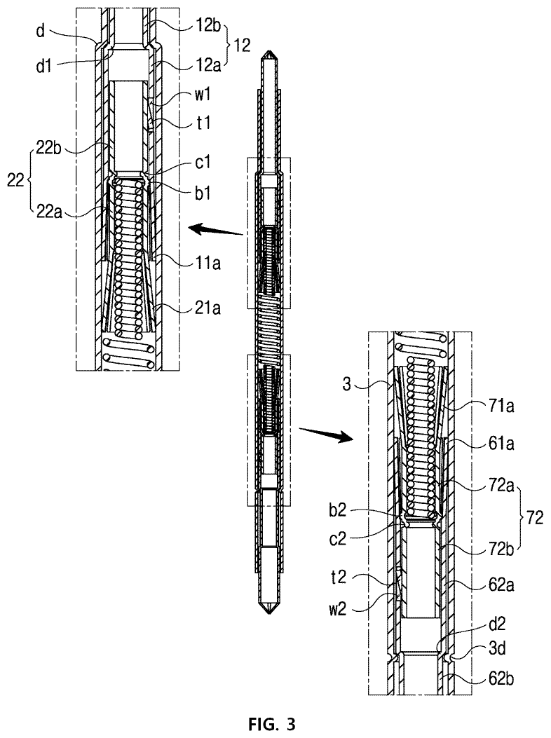

In the first brush set 11, a plurality of brushes 11a with one side thereof connected and fixed to the first cylindrical portion 12 (1-1 cylindrical portion 12a) and the other side (free end) thereof elastically contacting the inner surface of the barrel 3 is arranged in an annular shape along the circumference of the first cylindrical portion 12. In the first brush set 11, each brush is a straight strap, and before assembling the first plunger module 1 to the barrel 3, the first brush set 11 forms a conical shape and is connected to the first cylindrical portion 12 with a gap between the brushes. When the first plunger module 1 is assembled to the barrel 3, the ends of the conical shaped first brush set 11 are brought together so as to be close to a cylinder shape (see FIG. 3). Before assembling the plunger module 1 to the barrel 3, the maximum outer diameter encompassing the brushes in the first brush set 11 is larger than the inner diameter of the barrel 3 with which the first brush set 11 contacts.

The second plunger part 20 includes the second brush set 21 and a second cylindrical portion 22, and is formed by a process including bending, blanking, and coining of a single punched flat material.

The second cylindrical portion 22 has a substantially cylindrical shape that is interpolated into the first cylindrical portion 12 and fixed to the first cylindrical portion 12. The second cylindrical portion 22 includes the 2-1 cylindrical portion 22a that provides a base for fixing the second brush set 21, and a 2-2 cylindrical portion 22b coupled to the inside of the 1-1 cylindrical portion 12a. In the middle of the 2-2 cylindrical portion 22b, the locking piece t1 is formed by blanking in an approximately “E” shape, and one end of the locking piece is fixed to the opposite side of the second brush set, and the free end of the locking piece faces diagonally outward in the direction of the second brush set. By placing the free end of the first locking piece t1 on the first window w1, the second plunger part is prevented from being separated from the first plunger part.

In the second brush set 21, a plurality of brushes with one side thereof connected and fixed to the second cylindrical portion 22 and the other side thereof elastically contacting the inner surface of the barrel 3 is arranged in an annular shape on the circumference of second cylindrical portion 22. In the second brush set 21, each brush is a straight strap, and before assembling the first plunger module 1 to the barrel 3, the second brush set 21 forms a conical shape and is connected to the second cylindrical portion 22 with a gap between the brushes. When the first plunger module 1 is assembled to the barrel 3, the ends of the conical shaped second brush set 21 are brought together so as to be close to a cylinder shape (see FIG. 3). Before assembling the plunger module 1 to the barrel 3, the maximum outer diameter encompassing the brushes in the second brush set 21 is larger than the inner diameter of the barrel 3 with which the second brush set 21 contacts.

At the boundary between the 2-1 cylindrical portion 22a and the 2-2 cylindrical portion 22b, an annularly convex annular convex portion b1 and an annularly concave annular concave portion c1 are sequentially formed. The annular concave portion c1 prevents further entry of the coil spring 4, and the annular convex portion b1 functions to spread the first brush set and prevents the second plunger part from further entering the inside of the first plunger part.

The annular area on the inner side of the barrel where the first brush set is in contact and the annular area on the inner side of the barrel where the second brush set is in contact are separated by a certain distance in the longitudinal direction, and even when the plunger module operates, the two areas maintain the same distance, and the two brush sets move by sliding on the inner surface of the barrel.

The second plunger module 2 includes the fourth plunger part 60 and the fifth plunger part 70. The fourth plunger part 60 has many aspects similar to the first plunger part 10, and the fifth plunger part 70 has many aspects similar to the second plunger part 20.

The second plunger module 2 includes the fourth plunger part 60 and the fifth plunger part 70 that are integrally coupled to each other, which means the fourth brush set 61 and the fifth brush set 71 are also integrally coupled to each other. Thus, when the pogo pin operates, all components constituting the second plunger module move together, and the fourth brush set 61 and the fifth brush set 71 arranged at a certain distance apart in the longitudinal direction also move together.

The fourth plunger part 60 includes: the fourth brush set 61; a fourth cylindrical portion 62 having a substantially cylindrical shape and including a 4-1 cylindrical portion 62a, a 4-2 cylindrical portion 62b, and a 4-3 cylindrical portion 62c; and a fourth probe portion 63, and constitutes a single part in which the three components (fourth brush set 61, fourth cylindrical portion 62, and fourth probe portion 63) are connected in order. The fourth probe portion 63 is a part for electrical contact with the outside, and the fourth plunger part 60 is formed by a process including bending, coining, blanking, and plating of a single punched flat material.

The fourth cylindrical portion 62 includes the 4-1 cylindrical portion 62a that serves as a base on which the brushes of the fourth brush set may be fixed, the 4-2 cylindrical portion 62b connected to the 4-1 cylindrical portion 62a with a step d2 and having an outer diameter smaller than that of the 4-1 cylindrical portion 62a, and the 4-3 cylindrical portion 62c connected to the 4-2 cylindrical portion 62b with a step d3 and having an outer diameter larger than that of the 4-2 cylindrical portion 62b. Due to the annular concave portion 3d of the barrel (convex portion viewed from the inner surface of the barrel), the operating range of the 4-2 cylindrical portion 62b, which has the steps d2 and d3 on opposite sides, respectively, is limited. As the annular concave portion 3d of the barrel is placed in the space provided by the 4-2 cylindrical portion 62b, the operation of the second plunger module is restricted.

A second window w2 (see FIG. 3) punched out in the shape of a small square window is formed at the longitudinal center of the 4-1 cylindrical portion, and by placing the free end of the second locking piece t2 provided on a 5-2 cylindrical portion 72b on the second window w2, the fifth plunger part is prevented from being separated from the fourth plunger part.

In the fourth brush set 61, a plurality of brushes 61a with one side thereof connected and fixed to the fourth cylindrical portion 62 (4-1 cylindrical portion 62a) and the other side (free end) thereof elastically contacting the inner surface of the barrel 3 is arranged in an annular shape along the circumference of the fourth cylindrical portion 62. In the fourth brush set 61, each brush is a straight strap, and before assembling the second plunger module 2 to the barrel 3, the fourth brush set 61 forms a conical shape and is connected to the fourth cylindrical portion 62 with a gap between the brushes. When the second plunger module 2 is assembled to the barrel 3, the ends of the conical shaped fourth brush set 61 are brought together so as to be close to a cylinder shape (see FIG. 3). Before assembling the second plunger module 2 to the barrel 3, the maximum outer diameter encompassing the brushes in the fourth brush set 61 is larger than the inner diameter of the barrel 3 with which the fourth brush set 61 contacts.

The fifth plunger part 70 includes the fifth brush set 71 and the fifth cylindrical portion 72, and is formed by a process including bending, blanking, and coining of a single punched flat material.

The fifth cylindrical portion 72 has a substantially cylindrical shape that is interpolated into the fourth cylindrical portion 62 and fixed to the fourth cylindrical portion 62. The fifth cylindrical portion 72 includes the 5-1 cylindrical portion 72a that provides a base for fixing the fifth brush set 71, and the 5-2 cylindrical portion 72b coupled to the inside of the 4-1 cylindrical portion 62a. In the middle of the 5-2 cylindrical portion 72b, the locking piece t2 is formed by blanking in an approximately “r-” shape, and one end of the locking piece is fixed to the opposite side of the fifth brush set, and the free end of the locking piece faces diagonally outward in the direction of the fifth brush set. By placing the free end of the second locking piece t2 on the second window w2, the fifth plunger part is prevented from being separated from the fourth plunger part.

In the fifth brush set 71, a plurality of brushes with one side thereof connected and fixed to the fifth cylindrical portion 72 and the other side thereof elastically contacting the inner surface of the barrel 3 is arranged in an annular shape on the circumference of fifth cylindrical portion 72. In the fifth brush set 71, each brush is a straight strap, and before assembling the second plunger module 2 to the barrel 3, the fifth brush set 71 forms a conical shape and is connected to the fifth cylindrical portion 72 with a gap between the brushes. When the second plunger module 2 is assembled to the barrel 3, the ends of the conical shaped fifth brush set 71 are brought together (see FIG. 3). Before assembling the plunger module 2 to the barrel 3, the maximum outer diameter encompassing the brushes in the fifth brush set 71 is larger than the inner diameter of the barrel 3 with which the fifth brush set 71 contacts.

At the boundary between the 5-1 cylindrical portion 72a and the 5-2 cylindrical portion 72b, an annularly convex annular convex portion b2 and an annularly concave annular concave portion c2 are sequentially formed. The annular concave portion c2 prevents further entry of the coil spring 4, and the annular convex portion b2 functions to spread the fourth brush set and prevents the fifth plunger part from further entering the inside of the fourth plunger part.

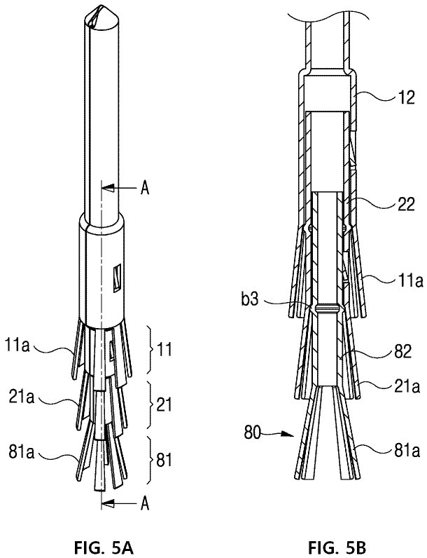

FIGS. 5A and 5B show a first modified example of the pogo pin according to the first embodiment of the present disclosure.

In the first modified example, a third plunger part 80 including a third brush set 81 is further combined with the second plunger part 20 so that three brush sets are configured in a single plunger module.

The third plunger part 80 includes: a third cylindrical portion 82 fitted into the second cylindrical portion 22 of the second plunger part 20; and a third brush set 81 in which a plurality of brushes 81a with one end thereof fixed to the third cylindrical portion 82 and the other end (free end) thereof elastically contacting the barrel 3 is arranged in an annular shape.

The annular area on the inner side of the barrel where the first brush set is in contact, the annular area on the inner side of the barrel where the second brush set is in contact, and the annular area on the inner side of the barrel where the third brush set is in contact are separated by a certain distance in the longitudinal direction, and even when the plunger module operates, the three areas maintain the same distance, and the three brush sets move by sliding on the inner surface of the barrel. Although it has been described as having a three-stage brush set, configuration with four or more stages is also possible.

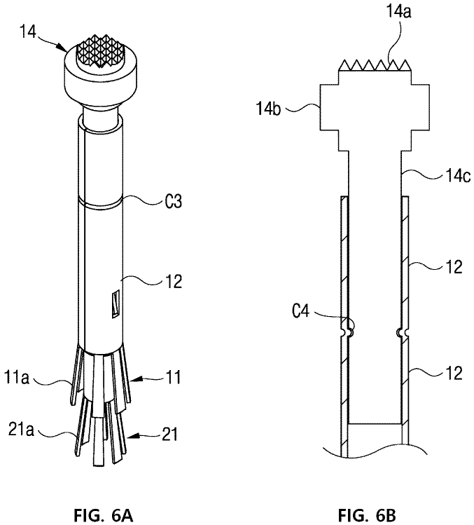

FIGS. 6A and 6B show a second modified example of the pogo pin according to the first embodiment of the present disclosure.

In the second modified example, a separate part machined from a lump of metal is used to construct the probe of the plunger module. A probe part 14 includes: a contact portion 14a in which sharp protrusions are arranged for electrical contact with the outside; a head portion 14b with the contact portion 14a formed on the upper side thereof and that is thick and short, and roughly cylindrical in shape; and a pillar portion 14c extending in the longitudinal direction from the head portion to be thinner than the head portion.

The probe part is coupled to the first plunger part by engaging an annular concave portion c4 formed in the pillar portion 14c of the probe part with an annular concave portion c3 formed in the upper part of the first cylindrical portion 12.

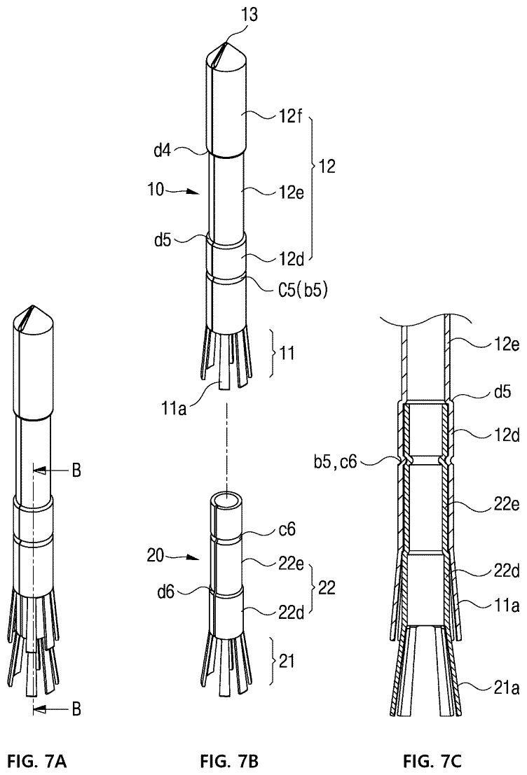

FIGS. 7A to 7C show a third modified example of the pogo pin according to the first embodiment of the present disclosure.

In the third modified example, the manner in which the first plunger part and the second plunger part are coupled to each other, or the manner in which the fourth plunger part and the fifth plunger part are coupled to each other are different from the first embodiment. In the following, the modification of the first plunger part and the second plunger part will be described, but the modification of the fourth plunger part and the fifth plunger part are also the same, and the description of other identical or similar parts may be omitted.

In the third modified example, the window and the locking piece are not used, and the annular convex portion and the annular concave portion are used to couple the first plunger part and the second plunger part. On the inner surface of the first cylindrical portion 12, an annular convex portion b5 (based on the inner surface) is formed, in which a protrusion convex inwardly is formed in an annular shape along the circumference of the first cylindrical portion 12. In other words, the protrusion may be referred to as an annular concave portion c5 (based on the outer surface) in which an inwardly concave groove is formed in an annular shape along the circumference of the first cylindrical portion 12 on the outer surface of the first cylindrical portion 12.

In addition, on the outer surface of the second cylindrical portion 22, an annular concave portion c6 is formed in an annular shape along the circumference of the second cylindrical portion 22, and by seating the annular concave portion c6 on the annular convex portion b5, the second cylindrical portion 22 (2-1 cylindrical portion 22e) is connected to the first cylindrical portion 12 (1-1 cylindrical portion 12d).

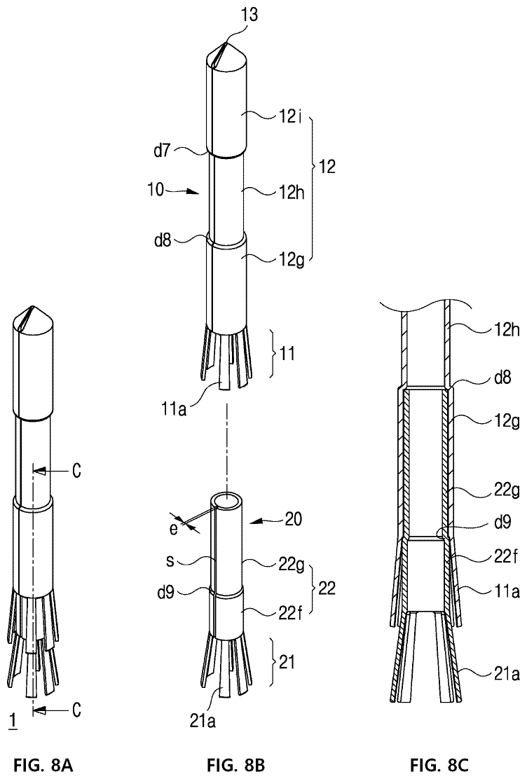

FIGS. 8A to 8C show a fourth modified example of the pogo pin according to the first embodiment of the present disclosure.

In the fourth modified example, the manner in which the first plunger part and the second plunger part are coupled to each other, or the manner in which the fourth plunger part and the fifth plunger part are coupled to each other are different from the first embodiment. In the following, the modification of the first plunger part and the second plunger part will be described, but the modification of the fourth plunger part and the fifth plunger part are also the same, and the description of other identical or similar parts may be omitted.

On the outer side of the second cylindrical portion 22 in the longitudinal direction, a 2-1 cylindrical portion 22g (also referred to as a “second coupling cylindrical portion”) is provided to fit into a 1-1 cylindrical portion 12g (also referred to as a “first coupling cylindrical portion”) located on the longitudinal inner side of the first cylindrical portion 12 (toward the center of the pogo pin in the longitudinal direction) and having a cylindrical shape. Before the second coupling cylindrical portion is coupled to the first coupling cylindrical portion, the outer diameter of the second coupling cylindrical portion is larger than the inner diameter of the first coupling cylindrical portion, and a slit s is formed along the longitudinal direction in the second coupling cylindrical portion, and as the second coupling cylindrical portion is coupled to the first coupling cylindrical portion, the width of the slit s is reduced or disappears.

The width of the slit s of FIG. 8B shows a width e after assembly (coupling), and the width of the slit before assembly after manufacturing the second plunger part is larger than that shown in FIG. 8B. The cross section of the second plunger part (second coupling cylindrical portion) before assembly is approximately “C” shaped with a larger slit, and when assembled, the outer diameter of the second coupling cylindrical portion is reduced to enter the first coupling cylindrical portion of the first plunger part. After entering, the second coupling cylindrical portion of the second plunger part tries to expand the outer diameter thereof due to elasticity, and accordingly, the second coupling cylindrical portion remains tightly fitted in the first coupling cylindrical portion.

The first plunger part 10 includes: a first brush set 11; a first cylindrical portion 12 having a substantially cylindrical shape and including the 1-1 cylindrical portion 12g, a 1-2 cylindrical portion 12h, and a 1-3 cylindrical portion 12i; and a first probe portion 13, and constitutes a single part in which the three components (first brush set 11, first cylindrical portion 12, and first probe portion 13) are connected in order.

The first cylindrical portion 12 includes the 1-1 cylindrical portion 12g that serves as a base on which the brushes of the first brush set may be fixed, the 1-2 cylindrical portion 12h connected to the 1-1 cylindrical portion 12g (also referred to as the “first coupling cylindrical portion”) with a step d8 and having an outer diameter smaller than that of the 1-1 cylindrical portion, and the 1-3 cylindrical portion 12i connected to the 1-2 cylindrical portion with a step d7 and having an outer diameter larger than that of the 1-2 cylindrical portion. Due to the annular concave portion of the barrel (convex portion viewed from the inner surface of the barrel), the operating range of the 1-2 cylindrical portion 12h, which has the steps d8 and d7 on opposite sides, respectively, is limited. As the annular concave portion of the barrel is placed in the space provided by the 1-2 cylindrical portion, the operation of the first plunger module is restricted.

The second plunger part 20 includes a second brush set 21 and a second cylindrical portion 22. The second cylindrical portion 22 has a substantially cylindrical shape that is interpolated into the first cylindrical portion 12 and fixed to the first cylindrical portion 12, and includes: a 2-1 cylindrical portion 22f providing a base for fixing the second brush set 21; and the 2-2 cylindrical portion 22g coupled to the inside of the 1-1 cylindrical portion 12g (also referred to as the “second coupling cylindrical portion”).

The second cylindrical portion 22, to be specific, the upper end (opposite the second brush set in the longitudinal direction) of the 2-2 cylindrical portion 22g (second coupling cylindrical portion) is set to engage the step d8. The length of the second coupling cylindrical portion is equal to or longer than the length of the first coupling cylindrical portion, and the outer diameter of the 1-2 cylindrical portion provided successively to the first coupling cylindrical portion is formed to be smaller, thereby creating the step d8.

According to the third modified example, since the second coupling cylindrical portion is in close contact with the first coupling cylindrical portion, the electrical resistance between the first and second cylindrical portions is significantly reduced.

According to the third modified example, even without forming a window/locking piece or annular concave portion/annular convex portion, etc., it is possible to maintain the coupling between the first plunger part (hereinafter the same applies to the fourth plunger part) and the second plunger part (hereinafter the same applies to the fifth plunger part). By constructing the second cylindrical portion (the second coupling cylindrical portion) to be inserted into the first cylindrical portion (the first coupling cylindrical portion), the second plunger part and the first plunger part are prevented from being separated from each other during the manufacturing process. In addition, when the manufacturing process is completed, the first plunger part and the second plunger part are stored while being elastically supported by the coil spring inside the barrel, and thus separation of the second plunger part and the first plunger part from each other does not occur.

Meanwhile, after assembly is completed, the pressure of the coil spring pushes the second plunger part toward the first plunger part, but the depth into which the second cylindrical portion enters the first cylindrical portion may be limited by the configuration such as the set step d8.

Furthermore, according to the present disclosure including the first embodiment, in the plunger module, since the brush set is composed of two or more stages (multi-stage configuration), the contact area where the plunger module contacts the barrel is significantly increased, and the total contact resistance between the plunger module and the external barrel may be further reduced. As a result, the electrical resistance on the main electrical path [first plunger module—barrel—second plunger module] is significantly reduced, and current carrying capabilities of the pogo pin may be significantly enhanced.

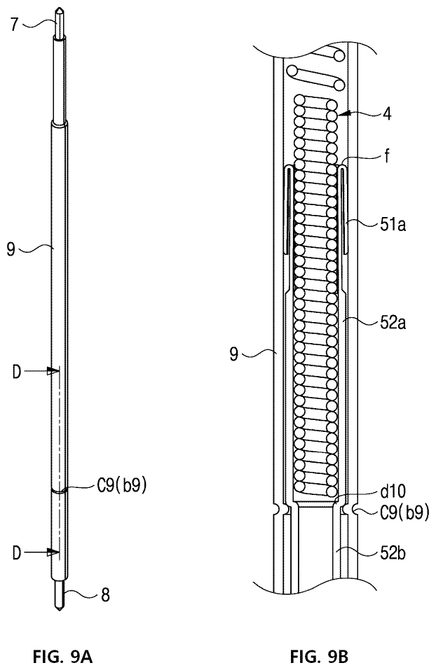

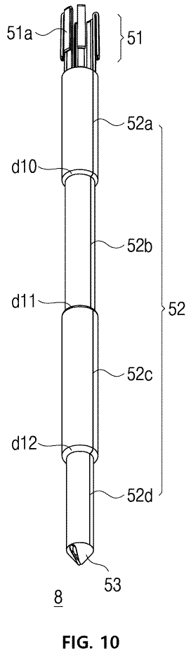

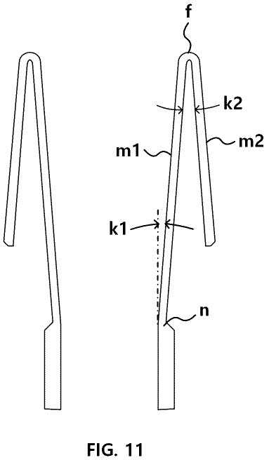

FIG. 9 shows a pogo pin according to a second embodiment of the present disclosure, with FIG. 9A being a perspective view and FIG. 9B being a cross-sectional view taken along the line D-D. FIG. 10 is a perspective view showing a first plunger in the pogo pin according to the second embodiment of the present disclosure. FIG. 11 is a cross-sectional view showing a brush in the pogo pin according to the second embodiment of the present disclosure.

Hereinafter, the pogo pin according to the second embodiment of the present disclosure will be described using FIGS. 9 and 11, and description of parts that are the same or similar to the pogo pin according to the first embodiment may be omitted.

A first plunger 8 and a second plunger 7 are guided by a barrel 9 and the length of each of the first plunger 8 and the second plunger 7 exposed to the outside of the barrel 9 is variable. The first plunger 8 and the second plunger 7 are constructed on opposite sides of the pogo pin in the longitudinal direction and are elastically supported by a coil spring 4.

In the pogo pin according to the second embodiment of the present disclosure, one or both of the first plunger 8 or the second plunger 7 may be the plunger shown in FIG. 10. It is desirable that the second plunger 7 may be configured to have two or more brush sets, like the first plunger module according to the first embodiment of the present disclosure, or may be configured like the first plunger part with a single brush set. The second plunger 7 is configured on the opposite side of the first plunger 8. The second plunger 7 is provided with a brush set in which a plurality of brushes with one side thereof fixed and the other side thereof elastically contacting the inner surface of the barrel 9 is arranged in an annular shape. Each of the plurality of brushes in the brush set is a straight strap, and the first plunger 8 is configured like the plunger shown in FIG. 10.

The first plunger 8 includes a first brush set 51 in which a plurality of brushes 51a with one side thereof fixed and the other side thereof elastically contacting the inner surface of the barrel 9 is arranged in an annular shape. Each of the plurality of brushes in the first brush set 51 is strap shaped but is shaped like a hook bent at least 135 degrees in the opposite direction in the middle part thereof.

Each brush is bent at a bending point f in the middle, and is bent by more than 135 degrees before assembling the first plunger to the barrel. Each brush may be divided into a first strap portion m1 and a second strap portion m2 centered on the bending point f, and the ratio occupied by the first strap portion m1 and the second strap portion m2 may be adjusted.

Before assembling the first plunger to the barrel, the first strap portion m1 is slightly bent outward (radial direction with respect to the central axis) around a reference point n so as to have an angle kl with respect to the direction of extension (longitudinal direction of the pogo pin) of the first cylindrical portion (1-1 cylindrical portion), and the second strap portion m2 is bent at least 135 degrees around the bending point f with respect to the first strap portion m1.

The first cylindrical portion 52 includes: a 1-1 cylindrical portion 52a that serves as a base on which the brushes of the first brush set may be fixed; a 1-2 cylindrical portion 52b connected to the 1-1 cylindrical portion 52a with a step d10 and having an outer diameter smaller than that of the 1-1 cylindrical portion; a 1-3 cylindrical portion 52c with a step d11 and having an outer diameter larger than that of the 1-2 cylindrical portion; a 1-4 cylindrical portion 52d with a step d12 and having an outer diameter smaller than that of the 1-3 cylindrical portion; and a probe portion 53 for electrical contact with the outside.

Due to an annular concave portion c9 of the barrel (annular convex portion b9 viewed from the inner surface of the barrel), the operating range of the 1-2 cylindrical portion, which has the steps d10 and d11 on opposite sides, respectively, is limited. Conversely, as the annular concave portion of the barrel is placed in the space provided by the 1-2 cylindrical portion, the operation of the first plunger module is restricted.

When the pogo pin is assembled, the second plunger 7 is inserted from an opening at one end of the barrel (the lower end in FIG. 9A, the side where the first plunger is coupled) toward the other end of the barrel, and then the coil spring 4 is inserted. To this end, the outer diameter at one end (the lower end) of the barrel is the same as the outer diameter of the central part of the barrel, and the opening at one end (the lower end) of the barrel is larger than an opening at the other end of the barrel.

Then, the first plunger 8 is inserted, and at this time, the first plunger 8 is inserted in the reverse direction (reverse insertion) starting from the first brush set 51 using the opening at one end of the barrel. When inserting the first plunger 8 in the reverse direction, the brush set is retracted and inserted, but compared to when assembled in the first embodiment, the brush set may be more easily inserted into the opening because the brushes are bent. In addition, during the insertion process, the brush set needs to ride over the annular convex portion b9 on the inner side of the barrel, but a brush set with bent brushes may more easily ride over the annular convex portion b9.

Meanwhile, in the case of the first embodiment, the fourth or fifth brush set has a side that makes it difficult to ride over the convex portion 3d (annular concave portion when viewed from the outer side of the barrel) on the inner side of the barrel. To make this easier, the brush set of the first embodiment may be modified to be slightly bent like a fish hook at the end of each brush in the direction of the axis center of the pogo pin.

In the pogo pin according to the second embodiment of the present disclosure, the first strap portion m1, which is a cantilever beam, exhibits an elastic behavior based on the reference point n, which is a first acting point, and the second strap portion m2, which is another cantilever beam, exhibits an elastic behavior based on the bending point f, which is a second action point. Accordingly, an elastic distance of the brush is the overlap between an elastic distance created by the first strap portion m1 and an elastic distance created by the second strap portion m2, and thus the elastic distance of the brush may be increased.

What is claimed is:

1. A pogo pin comprising:
a plunger module guided by a barrel and whose length exposed to an outside of the barrel is variable,
wherein the plunger module comprises:
a first brush set in which a plurality of brushes with a first side thereof fixed and a second side thereof elastically contacting an inner surface of the barrel is arranged in an annular shape; and
a second brush set in which a plurality of brushes with a first side thereof fixed and a second side thereof elastically contacting the inner surface of the barrel is arranged in an annular shape.

2. A pogo pin comprising:
a cylindrical barrel;
one or two plunger modules guided by the barrel and whose length exposed to an outside of the barrel is variable; and
a coil spring elastically supporting the one or two plunger modules,
wherein at least one plunger module of the one or two plunger modules comprises:
a first plunger part comprising: a first cylindrical portion; and a first brush set in which a plurality of brushes with a first side thereof connected to the first cylindrical portion and a second side thereof elastically contacting an inner surface of the barrel is arranged in an annular shape; and
a second plunger part comprising: a second cylindrical portion interpolated into the first cylindrical portion and fixed to the first cylindrical portion; and a second brush set in which a plurality of brushes with a first side thereof connected to the second cylindrical portion and a second side thereof elastically contacting the inner surface of the barrel is arranged in an annular shape.

3. The pogo pin of claim 1, wherein a maximum outer diameter encompassing the brushes in the first brush set before assembling the plunger module to the barrel is larger than an inner diameter of the barrel with which the first brush set contacts, and
a maximum outer diameter encompassing the brushes in the second brush set before assembling the plunger module to the barrel is larger than the inner diameter of the barrel with which the second brush set contacts.

4. The pogo pin of claim 2, wherein in the first brush set, each brush is a straight strap, and before assembling a first plunger module of the one or two plunger modules to the barrel, the first brush set forms a conical shape and is connected to the first cylindrical portion with a gap between the brushes, and
in the second brush set, each brush is a straight strap, and before assembling the first plunger module of the one or two plunger modules to the barrel, the second brush set forms a conical shape and is connected to the second cylindrical portion with a gap between the brushes.

5. The pogo pin of claim 2, wherein the first plunger part is made by a process including bending a single punched flat material, and
the second plunger part is made by a process including bending a single punched flat material.

6. The pogo pin of claim 5, wherein on an inner surface of the first cylindrical portion, an annular convex portion in which an inwardly convex protrusion is formed in an annular shape along a circumference of the first cylindrical portion is provided, whereas
on an outer surface of the second cylindrical portion, an annular concave portion in which an inwardly concave groove is formed in an annular shape along a circumference of the second cylindrical portion is provided, and
as the annular concave portion is seated on the annular convex portion, the second cylindrical portion is fixed to the first cylindrical portion.

7. The pogo pin of claim 5, wherein a second coupling cylindrical portion of a cylindrical shape is provided on an outer side of the second cylindrical portion in a longitudinal direction so as to fit into an inner surface of a first coupling cylindrical portion, which is located on a longitudinal inner side of the first cylindrical portion and has a cylindrical shape,
wherein before the second coupling cylindrical portion is coupled to the first coupling cylindrical portion, an outer diameter of the second coupling cylindrical portion is larger than an inner diameter of the first coupling cylindrical portion, and
a slit is formed along a longitudinal direction in the second coupling cylindrical portion, wherein a width of the slit is reduced or disappears as the second coupling cylindrical portion is coupled to the first coupling cylindrical portion.

8. The pogo pin of claim 7, wherein a length of the second coupling cylindrical portion is equal to or longer than a length of the first coupling cylindrical portion, so that an upper end of the second coupling cylindrical portion is caught by a step created in the first cylindrical portion, and an outer diameter of the cylindrical portion provided successively to the first coupling cylindrical portion is formed to be smaller than that of the first coupling cylindrical portion, thereby creating the step.

9. The pogo pin of claim 5, further comprising:
a third plunger part comprising: a third cylindrical portion fitted into the second cylindrical portion of the second plunger part; and a third brush set in which and a plurality of brushes with a first end thereof fixed to the third cylindrical portion and a free end thereof elastically contacting the barrel is arranged in an annular shape.

10. The pogo pin of claim 2, wherein a maximum outer diameter encompassing the brushes in the first brush set before assembling the at least one plunger module of the one or two plunger modules to the barrel is larger than an inner diameter of the barrel with which the first brush set contacts, and
a maximum outer diameter encompassing the brushes in the second brush set before assembling the at least one plunger module of the one or two plunger modules to the barrel is larger than the inner diameter of the barrel with which the second brush set contacts.

11. A pogo pin comprising:
a first plunger guided by a barrel and whose length exposed to an outside of the barrel is variable,
wherein the first plunger comprises:
a first brush set in which a plurality of brushes with a first end thereof fixed and a second end thereof elastically contacting an inner surface of the barrel is arranged in an annular shape,
wherein in the first brush set, each of the brushes is strap shaped but is shaped like a hook bent at least 135 degrees, before assembling the first plunger to the barrel in a middle part thereof.

12. The pogo pin of claim 11, further comprising:
a second plunger guided by the barrel, whose length exposed to an outside of the barrel is variable, and configured opposite the first plunger,
wherein the second plunger comprises:
a second brush set in which a plurality of brushes with a first end thereof fixed and a second end thereof elastically contacting the inner surface of the barrel is arranged in an annular shape,
wherein in the second brush set, each of the brushes is a straight strap.
